(19) United States
(12) Patent Application Publication
(10) Pub. No.: US 2003/0172045 A1
(43) Pub. Date: Sep. 11, 2003

(54) System and method for automation of ASIC synthesis flow

(76) Inventor: Yossi Rindner, Reut (IL)

Correspondence Address: BROWDY AND NEIMARK, P.L.L.C., 624 NINTH STREET, NW, SUITE 300, WASHINGTON, DC, 20001-5303, US

(21) Appl. No.: 10/091,393

(22) Filed: Mar. 7, 2002

(51) Int. Cl. G06F 7/00

(52) U.S. Cl. 707/1

(57) ABSTRACT

A method and apparatus for interfacing between first and second successive stages of an ASIC synthesis tool, wherein output data is received at an output of the first stage, script files are automatically generated and fed together with the output data to the second stage for processing the output data in accordance with information contained in the script files.

### FIELD OF THE INVENTION

This invention relates to the field of computerized electronic circuit design.

### BACKGROUND OF THE INVENTION

ASICs (Application Specific Integrated Circuit) are electronic components or chips developed according to unique specifications defined by the ASIC designer. This component is built from millions of transistors which are the smallest logic parts comprising the ASIC. Many technology companies develop ASICs, using various software tools, for the different design stages. The design flow is described below:

The first stage of ASIC design is drawing up the Specifications—documents describing the requirements and functionality of the ASIC. The specifications describe the functionality and the expected performance (timing) of the chip.

ASIC are comprised of memory elements (registers) and arithmetic elements (gates). The registers and gates are cascaded, such that when the data memorized by a register is processed by the following gate, the result is memorized again by the following register. The ASIC designer determines which gates should reside between the registers, how many of them to use, and their order—commonly referred to as RTL (Register Transfer Level) design.

The RTL design should by described in a way that supports computerized development of the ASIC; i.e. the design should be described by machine-readable code, that is—a programming language generally known as HDL (Hardware Description Language). For that purpose there are several languages known in the art, common among them being Verilog and VHDL.

Prior to implementing and manufacturing the ASIC, the ASIC designer has to test the design, debug errors and simulate the ASIC's functionality, to see it complies with the requirements as defined by the specifications. This stage is referred to as simulation and verification.

Next is the Implementation stage—At this stage the RTL previously designed by HDL code is transferred into a more specific description, characterized by a lower level of abstraction that supports later manufacture of the ASIC. This description can be schematic or it can also be in HDL. The tools used for this stage are commonly referred to as synthesis tools, and the resulting description is referred to as a netlist.

There are several companies producing synthesis tools. Each product uses the same RTL code, and the end products of all these tools are netlists having a common format. However, the act of producing the netlists from the RTL code is typically done in stages each performed by a respective tool. These tools may require different input parameters and may operate according to different syntax. In this case, conversion is required to render the output of one stage compatible with the input to a successive stage. Conversion tools are known per se, but these add yet more stages to the process and further increase the complexity and likelihood of errors. The manner in which the data is cascaded from one stage to the next is typically done manually, which causes confusion and long learning curves among ASIC designers.

The next stage virtually places the netlist on silicon: software tools are used to emulate the real physical location of the registers and gates in the ASIC, viewing them on screen or by printable drawings. This is the layout stage.

The resulting layout is tested against timing specifications—STA (Static Timing Analysis), since it may affect the performance of the chip. The static analysis tools perform the STA, using the output of the synthesis stage as their input. If timing improvements are required, the process returns to the RTL coding and verification stage, to improve the design.

Last is the production stage—production of a prototype, in silicon, of the designed ASIC.

Owing to the complex nature of ASIC design there is a risk that errors will be introduced during the design process. This risk increases as parts of the design process are manually controlled. It is therefore preferable to automate the process of ASIC design, and all its stages, not only to improve efficiency but also to avoid the manual introduction of errors into the design which may impact later on the ASIC manufacture stage.

This requirement has been partially addressed in the art. For example, U.S. Pat. No. 6,185,726 (Chou; Chen-Chi) “System and method for efficiently designing integrated circuit devices” describes a system and method for efficiently designing integrated circuits. It provides a verification manager for verifying an integrated circuit design, a synthesis manager for synthesizing the integrated circuit design, and a backend manager for implementing the integrated circuit design. It also provides a processor for simultaneously controlling the verification manager, the synthesis manager, and the backend manager to create the integrated circuit design. The system and method generates a series of regression checkpoints controlled by the verification manager, and a series of timing checkpoints controlled by the synthesis manager to facilitate and expedite the integrated circuit design procedure, U.S. Pat. No. 6,185,726 offers no description of the various managers referred therein but is concerned mainly with their mutual interaction.

### SUMMARY OF THE INVENTION

It is therefore an object of the invention to provide a method and system that enhances the computerized ASIC design process.

The invention relates to the synthesis stage of the ASIC design. It activates the synthesis tools, automatically generating any required scripts and data structures, thereby supporting different synthesis tools. The resulting netlist may be customized by the operator for specific needs.

ASIC design sometimes requires stepping back a number of design steps, or viewing previously written code. For this purpose, the invention provides an automatic integration with version control tools, automatically tracking modification to the RTL and netlist codes, developed in the design process. Using version control tools can help also in organizing the ASIC integration process, as versions are properly marked. Automatically integrating version control tools into the ASIC design process encourages and simplifies their usage.

To perform timing analysis for any HDL code, the ASIC designer develops scripts that formulate the constraints for the test, i.e., description of the input signals to the ASIC or to blocks within it. While some of the timing analysis tools use propriety languages to describe the constraint scripts, others use more conventional and common languages, such as Tcl-Tk. The invention provides a method for integration of transcription tools, to support transcript of constraint scripts from one language to another.

The synthesis process is composed of two principal stages: analysis and compilation. The analysis stage performs parsing of the HDL code, scanning the sequence of input characters or input tokens in the HDL code to check their syntax and find syntax errors, if such exist, creating conventional HDL modules from the input code. The compilation creates the netlist from the parsed HDL code and from the constraints' scripts. The invention automates the process, while leaving it possible for the ASIC designer to intervene, by setting specific instructions for the tools or by manually modifying the files.

Synthesizing separately different blocks in, the same ASIC requires emulation of the other blocks, which may provide input to the current block and take part in creating its working environment. Formulating scripts, in a process referred to as Budget performs this emulation. The Budget scripts are used in the previously mentioned compilation process, while compiling the block. The scripts formulated in the budget stage must specify timing constraints and loads for the emulated inputs and output of the synthesized block.

The invention also supports computerized insertion of scan chains into the ASIC in the DFT (Design For Test) process. The scan chains support an effective test of the later manufactured ASIC, testing the functionality of the chip in a minimal time. Although the scan chains increase compilation time and the size of the netlist, they improve the testability of the manufactured ASIC, and this accounts for their high importance.

The produced netlist should be compared against the initial HDL developed in the ASIC design process, to check the agreement of both. This comparison is referred to as verification, and it is also composed of two stages: dynamic verification (real world signal emulation to the as yet virtual ASIC) and static verification (comparing the netlist with the HDL code to check their formal agreement). Dynamic verification is also known in the art as simulation, while static verification is referred to as formal verification. The formal verification can test the ASIC's functionality, and it significantly reduces the simulation time, although it is impossible to avoid the simulation test which checks also the timing of the ASIC.

The synthesis and tests described so far do not consider the physical location of the ASIC elements relative to each other, a location determined by the layout process. As the physical location affects the ASIC performance, a previously successfully verified ASIC, tested again after layout, may fail to fulfill the timing expectations specified for it. In such cases, it is necessary to add to the ASIC elements functioning to balance the ASIC timing, i.e. elements which speed-up or slow-down the ASIC performance. Therefore, based on the timing constraints specified by the budget stage, on the layout constraints generated by the ASIC designer and on the netlist generated by the synthesis stage, the physical compile performs a layout based synthesis, i.e. it locates speeded-up and slowed-down elements on the ASIC while moving and switching between elements already located on it by the synthesis stage in order to find vacant locations for all.

Testing the timing of an ASIC that passed the layout and/or the physical compile stages combines formal and static analysis in a stage referred to as physical STA. The physical STA tools perform timing analysis, using the output of the layout as their input, the output of the layout including Standard Delay Format (SDF) files which represents the actual delays on the physically placed netlist. An SDF file describes each element in the netlist and the delay concerned with it in a standard format known to those versed in the art.

However, after the successful termination of the layout and its accompanying stages (e.g. physical compile and physical STA) there may still be a need to insert some minor last moment changes to the netlist. According to the procedures described so far, modifying the RTL forces the ASIC designer to re-do the synthesis and layout stages, which are time consuming and expensive. Therefore it is possible to “manually” insert modifications to the netlist, a process known as ECO (Electrical Change Order). In the ECO process specific elements and connections can be inserted or removed by manually to the netlist. As the ECO modifies the RTL and the netlist, formal verification MUST be employed again to compare the equivalence of the newly created netlist against the initial RTL.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 is an exemplary interface supporting ASIC synthesis according to one embodiment of the invention.

FIG. 2 is a block diagram of one embodiment of the present invention of a synthesis manager.

FIG. 3 is a block diagram of the units composing the file manager module.

FIG. 4 is a block diagram presenting the synthesis module according to one embodiment of the invention.

FIG. 5 is a block diagram of the units composing the timing analysis module.

FIG. 6 is block diagram of the units composing the verification module.

FIG. 7 is a flowchart of the method steps automatically integrating synthesis, layout and timing analysis.

FIG. 8A is a flowchart of the method steps automatically integrating formal verification into the synthesis and layout stages.

FIG. 8B is a flowchart of the method steps automatically integrating formal verification into the layout and ECO stages.

### DETAILED DESCRIPTION OF THE INVENTION

The invention relates to a software tool for ASIC design that activates the synthesis tools and automatically generates any required scripts and data structures, thereby supporting different synthesis tools. The resulting netlist may be customized by the operator for specific needs.

The disclosed embodiment of a synthesis manager is a processor automatically activating the synthesis stages.

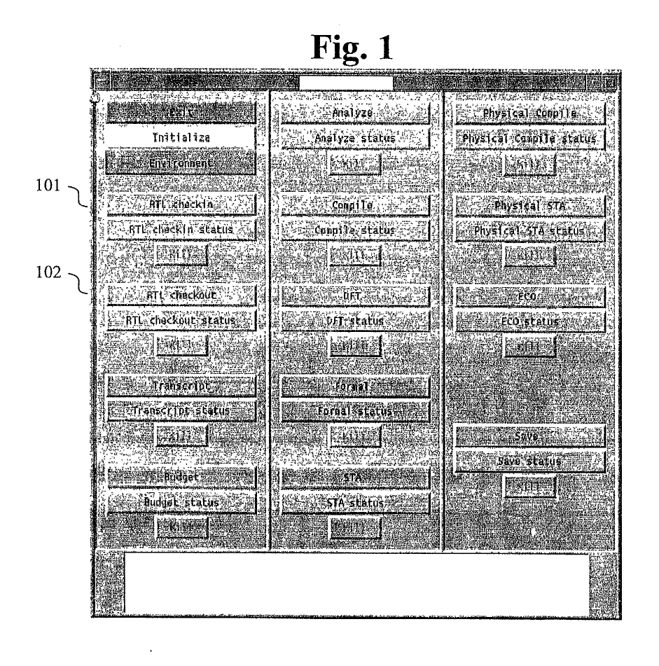

FIG. 1 illustrates an exemplary interface supporting ASIC synthesis manager according to one embodiment of the invention. The interface supports the activation of each synthesis stage, and the display of each stage's results and statistics, by selecting any selector, i.e. button, from the graphical interface. The illustrated embodiment support the synthesis process from its very first stages to the lasts, including file management operations such as checkin 101, checkout 102. Command files, i.e. scripts, relating to each selector are stored in the memory of the synthesis manager, to be automatically executed when the selector is selected.

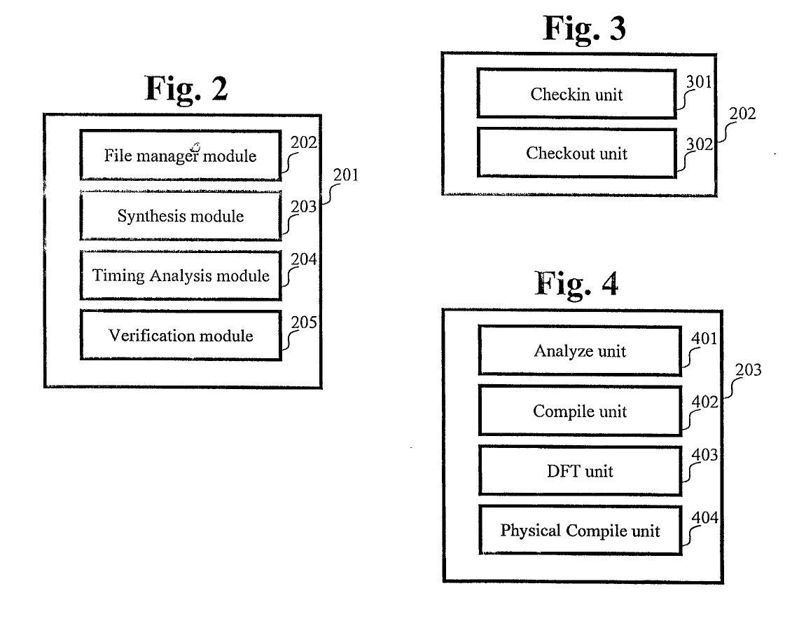

Referring to FIG. 2, a block diagram of one embodiment of the present invention of a synthesis manager 201 is shown. The synthesis manager 201 is composed of four modules: File manager module 202, synthesis module 203, timing analysis module 204, and verification module 205.

Files relating to the system are stored on disk for access by the memory of the synthesis manager. The files management operations supported simplify the file system interaction for the ASIC designer: ASIC design sometimes requires stepping back a number of design steps, for viewing or editing previously written code. For this purpose, the invention provides automatic integration with version control tools, automatically tracking modifications to files developed in the design process. Using version control tools can help also in organizing the ASIC integration process, as versions can be properly marked. Automatically integrating version control tools into the ASIC design process encourages and simplifies their usage. Version control tools are widely used in the market. Examples of commercially available version control tools are RCS, SCCS and CVS.

FIG. 3 presents a block diagram of the file manager module 202 in more detail, according to one embodiment. The illustrated file manager module comprises two units. The checkin unit 301 enables the ASIC designer to insert a list of one or more files into the version control tool. At any time in the future, the ASIC designer will be able to draw the files out from the version control tool (an operation known as checkout).

The list of files is fed into the checkin unit 301, for example in the form of a pre-prepared text file containing the list of filer names, or by interactive means such as an interactive graphical user interface. If the list contains at least one file, i.e. the list is not empty, the file manager automatically generates a script file (in some operating systems such files arm know for example, as batch files). The script file is generated, for example according to a pre-prepared template, which can be coded into the file manager code itself, or which can be inserted into external template files accessed by the file manager at run time, such as XML template files. The automatic creation of script files hides the specific version control tool from the ASIC designer, thereby enabling the use of different tools while keeping the same file manager interface. Following is an example for automatically generating a script file, based on a template file, for executing the checkout command on the UNIX's RCS version control tool. The generated script will execute the checkout command on each filename received as input. According to one embodiment, the input list of file names may be fed as a text file. For each file name in the list its directory destination (i.e. path) is also designated. The list of files according to the embodiment is described here:

FILE_NAME=ping.v PATH_NAME=/src/ASIC/local

FILE_NAME=pong.v PATH_NAME=/src/ASIC/local

According to the same embodiment, the template script file may take the form:

co-l $SPATH_NAME/$FILE_NAME

For every file in the input list of files the processor will switch the FILE_NAME value (in the example: “ping.v”) with the $FILE_NAME parameter in the template file, and the PATH_NAME value (in the example: “/src/ASIC/local”) with the $PATH_NAME parameter in the template file.

Therefore, in the last example, he following script will be automatically created:

co-l /src/ASIC/local/ping.v

co-l /src/ASIC/local/pong.v

When the ASIC designer selects the ckeckout unit's selector, the described scripts are automatically created and executed, to checkout both files (ping.v and pong.v) from the RCS version control tool and put their copy in the /src/ASIC/local directory.

The file manager module 202 also contains a checkout unit 302, enabling the ASIC designer to draw from the version control tool a list of one or more files. The checked-out files may be from any previously checked-in version, and not necessarily the last version inserted to the version control tool. Here, as already described for the checkin unit 301, files lists are fed into the file manager, and a script file is automatically generated.

RTL files (i.e. files containing HDL code) checked out from the version control tool are subjected to synthesis. According to the embodiment presented in FIG. 2, the synthesis is performed by the synthesis module 203. Attention is drawn now to FIG. 4, showing a block diagram presenting the synthesis module 203 according to one embodiment of the invention, and the units composing it: analyze unit 401, compile unit 402, DFT unit 403 and physical compile unit 404.

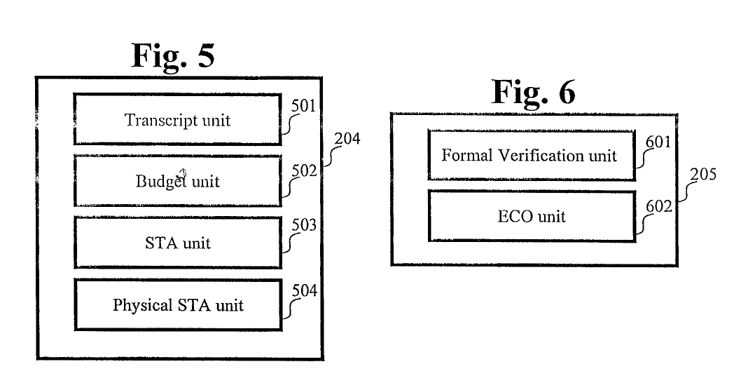

The analyze unit 401 performs analysis of the HDL code in the RTL file, generating proprietary data specific to each synthesis tool. The compile unit 402 then compiles proprietary modules with constraint scripts to generate a netlist. The constraint scripts are partially provided by the ASIC designer as script files and the others are script files are automatically generated by the budget unit 502 (FIG. 5). The DFT unit 403 then inserts scan chains into the generated netlist, and the physical compile unit 404 performs layout-based synthesis on the netlist.

Attention is drawn now to FIG. 5, showing a block diagram of the units composing the timing analysis module 204 illustrated also in FIG. 2. It will be recalled that timing analysis tests are performed throughout the ASIC design and development process, to assure the produced ASIC fulfils the timing requirements specified for it in the timing specification documents, which are part of the specifications.

The transcript unit 501 activates transcription tools for translating of constraint scripts from one language to another. Activation of transcription tools is performed separately on each script in a scripts' list fed into the unit as input, e.g. by a script (i.e. text) file or by an interactive user interface, by automatically generating an activation script based on a pre-prepared template script. Note that the transcript unit is a tool dependent unit, i.e., as the nit transcripts from one language to another, it may happen that its usage will be redundant if the constraints are originally written in the required language. For example: Synopsys' synthesis tool, called “DesignCompiler”, uses a proprietary scripting language called “dc_shell” to formulate the constraint scripts. However, Synopsys' STA tool, called “PrimeTime”, uses the industrial standard scripting language Tcl. The transcript unit 501 is used in this example to transcript from dc_shell to Tcl. However, recently Synopsys modified their DesignCompiler to support also the standard Tcl language, what renders the transcript unit redundant.

The budget unit 502 formulates a script emulating inputs and outputs for a specific block. To formulate the script, the budget unit uses the ASIC designer's defined timing constraints, in the form of script files, which define the timing requirements for the whole ASIC, i.e. the timing requirements from the ASIC's inputs and outputs. From these scripts the budget unit formulates the timing constraints for the specific block. Budgeting is known to those versed in the art, and is performed by STA tools, such as PrimeTime.

The STA unit 503 (Static Timing Analysis) tests the netlist resulting from the compilation and DFT units against the ASIC's timing specifications. It should be noted that the STA unit is not concerned with the relative physical location of elements in the post-layout ASIC, in contrast to the physical STA unit 504, which is.

The last module described by the presented embodiment is the verification module 205. FIG. 6 present a block diagram of the units composing the verification module 205. First is the formal verification unit 601, which compares the netlist with the HDL code to check their formal agreement, and the second is the ECO unit 602 which inserts last moment modifications into the post-layout netlist. The formal verification unit automatically generates scripts to compare the initial HDL against the synthesized netlist, against the post-layout netlist and against the post-ECO netlist. The automatically generated scripts are formed, based on a pre-prepared template scripts, such as by coding the template into the synthesis manager's code or by loading template scripts at run-time, for example: XML template files. To perform the ECO, the ECO unit 602 uses scripts fed by the ASIC designer, which describe the manually inserted modifications. The script is in any language that can be fed into the synthesis tool (such as dc_shell or Tcl), and it describes in detail the modifications, that is, the cuts (disconnections) and connections to be formed. Therefore the script is known to those versed in the art as cut-connect list.

Relationships exist between different units composing the ASIC synthesis process, as the ASIC designer passes through the different units and returns to some of them when errors occur.

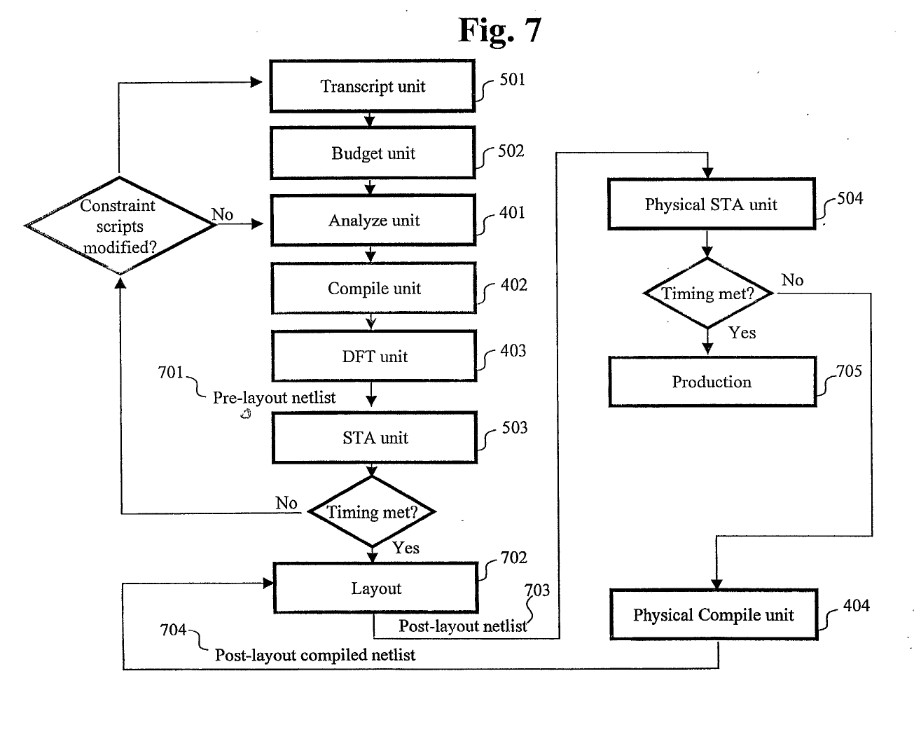

FIG. 7 shows a flowchart of the method steps automatically integrating synthesis, layout and timing analysis. While starting the development of new ASIC, the transcript unit 501 performs transcripts of the ASIC designer's supplied constraint scripts to the required language (if necessary), and the budget unit 502 automatically generates all other necessary constraint scripts. The HDL files are analyzed by the analyze unit 401, the result is compiled by the compile unit 402, and the DFT unit 403 inserts, scan chains into the generated netlist. The result is the pre-layout netlist 701. Before turning to the layout stage 702, it is necessary to test the timing of the pre-layout netlist 701 in order to make sure the timing specified for the ASIC is met, this test being performed by the STA At 503. Failing to meet the expected specified timing, the ASIC designer has to modify the HDL code or the constrain scripts he provided for the analyze unit 501. Note that the ASIC designer returns to the transcript unit 501 and to the budget unit 502 only in those cases when the constraint scripts where modified. In other cases, when only the HDL code was modified, the ASIC designer can skip the transcript unit 501 and the budget unit 502, and turn directly to the analyze unit 401, to the compile unit 402 and to tie DFT unit 403, to re-synthesize the ASIC. However, when the expected specified timing is met, the ASIC designer can continue directly to the layout stages 702 to generate the post-layout netlist 703. Again, it is necessary to test the post-layout netlist to check the specified timing is met a test performed by the physical STA unit 504. Meeting the expected timing specifications, the ASIC designer can handle the netlist to production 705. Failing to meet the specified timing in the physical STA unit's test the ASIC designer turns to the physical compile unit 404, which generates the post-layout compiled netlist 704 and handles it back to the layout 702 and to the physical STA unit 504 that tests the timing of the modified post-layout netlist 703.

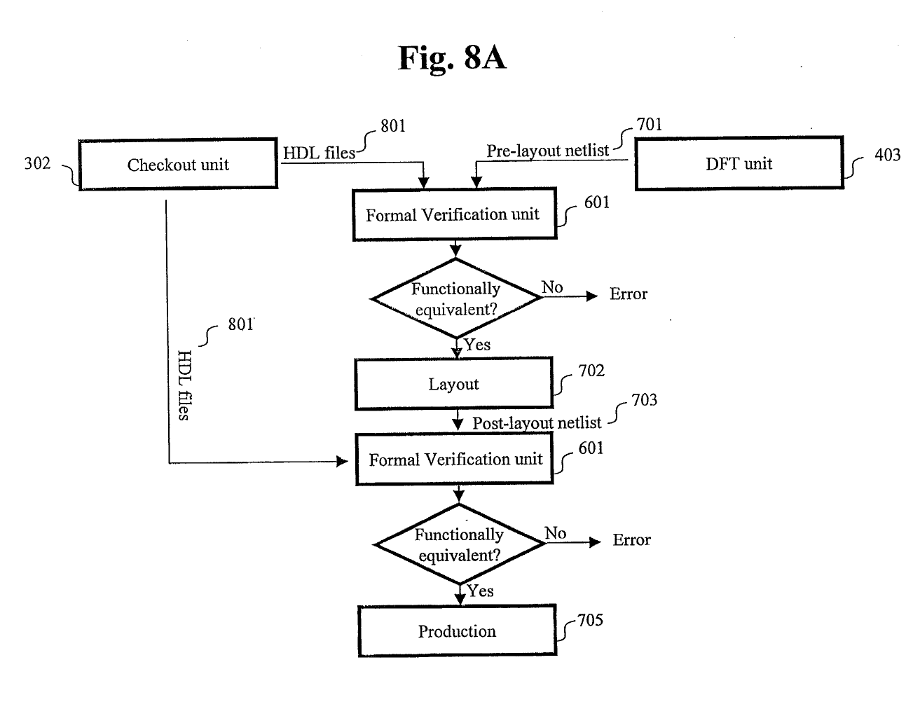

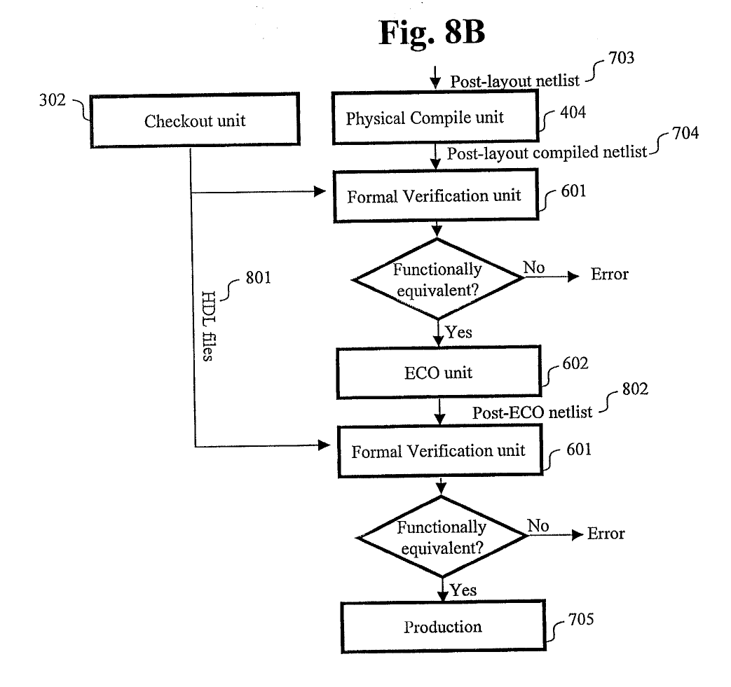

FIG. 8A shows a flowchart of the method steps automatically integrating formal verification into the synthesis and layout stages. Note that the formal verification unit 601 always compares a generated file against the initial HDL files 801 checked out from the version control tool by the checkout unit 302. The formal verification unit 601 initiates formal verification which is applied first an the pre-layout netlist 701 generated by the DFT unit 403, and on the HDL files 801 to check they are functionally equivalent. If they are found to be functionally different, the ASIC designer can deduce there was an error in the synthesis module (not shown). A functionally equivalent pre-layout netlist can be passed on to the layout stage 702, which generates the post-layout netlist 703. The post-layout netlist 703 is also subject to formal verification by the formal verification unit 601, checking its functional equivalence against the initial HDL files 801. A functionally equivalent netlist can be passed on to production 705.

FIG. 8B illustrates a flowchart of the method steps automatically integrating formal verification into the layout and ECO stages. In those cases when the ASIC designer chooses to employ the physical compile unit 404, the formal verification unit 601 must perform formal verification on the post-layout compiled netlist 704, to functionally compare it against the initial HDL files 801, checked out from the version control tool by the checkout unit 302. Here as before, the functionality must be kept equivalent in order to continue with the design process. At this stage the ASIC designer can insert manual changes into the post-layout compiled netlist 704 by the ECO unit 602. Note that this is an optional stage (in contrast to the mandatory stages of the ASIC design process), which generates the post-ECO netlist 802. The post-ECO netlist 802 must also be functionally compared against the initial HDL files 801 by the formal verification unit 601, to determine the generated post-ECO netlist 802 is functionally equivalent to them, and therefore ready for production 705.

Note that in the ASIC synthesis and design processes, it is impossible to split the integration of the timing analysis module (as illustrated by the flowchart shown in FIG. 7) from the integration of the verification module (as illustrated in FIG. 8A and FIG. 8B), and the split embodiments illustrated here are for convenience only, while the processes are combined.

In the method claims that follow, alphabetic characters and Roman numerals used to designate claim steps are provided for convenience only and do not imply any particular order of performing the steps.

It will also be understood that the apparatus according to the invention may be a suitably programmed computer. Likewise, the invention contemplates a computer program being readable by a computer for executing the method of the invention. The invention further contemplates a machine-readable memory tangibly embodying a program of instruction executable by the machine for executing the method of the invention.

The present invention has been described with a certain degree of particularity, and accordingly those versed in the art will readily appreciate that various alterations and modifications may be carried out without departing from the scope of the claims.

For example, while the preferred embodiment uses automatically generated scripts, scripts supplied from an external source and scripts generated by the first stage to feed into the second stage, it will be appreciated that there may be situations where script files are not provided by the first stage, or from an external source.

1. A method for interfacing between first and second successive stages of an ASIC synthesis tool, said method comprising:
(i) receiving output data at an output of the first stage,
(ii) automatically generating first script files, and
(iii) feeding said output data and said first script files to the second stage for processing the output data in accordance with information contained in the first script files.

2. The method according to claim 1 further comprising:
(iv) obtaining second script files as an output of the first stage, and
(v) feeding said second script files to the second stage for processing the output data in accordance with information contained in the second script files.

4. The method according to claim 3 further comprising:
(vi) obtaining third script files from an external source, and
(vii) feeding said third script files to the second stage for processing the output data in accordance with information contained in the third script files.

5. The method according to claim 1 including using a pre-prepared template for automatically generating the third script files.

6. An apparatus for interfacing between first and second successive stages of an ASIC synthesis tool, said apparatus comprising:
a processor,
a plurality of selectors coupled to the processor and each corresponding to a tool for performing a stage in an ASIC design, and
a memory coupled to the processor and storing therein respective command files relating to each of said selectors;
said processor being responsive to selection of at least one of the selectors for accessing the memory and executing commands associated therewith.

7. The apparatus according to claim 7, wherein the commands executed by the processor are extracted from the respective command file relating to each of said selected selectors.

8. The apparatus according to claim 8, wherein the command file relating to each of said selected selectors is automatically generated.

9. The apparatus according to claim 8, wherein the command file relating to each of said selected selectors is automatically generated according to a pre-prepared template.

10. The apparatus according to claim 9, wherein the pre-prepared template is part of the selected selector.

11. The apparatus according to claim 10, wherein the pre-prepared template is a pre-prepared external file.

12. The apparatus according to claim 12, wherein the pre-prepared external file is an XML, file.

13. The apparatus according to claim 7, wherein the commands executed by the processor are parts of each of said selected selectors.

14. The apparatus according to claim 7, wherein at least some of said selectors are operable via a graphical user interface.

15. A program storage device readable by machine, tangibly embodying a program of instructions executable by the machine to perform method steps for interfacing between first and second successive stages of an ASIC synthesis tool, said method comprising:
(i) receiving output data at an output of the first stage,
(ii) automatically generating first script files, and
(iii) feeding said output data and said first script files to the second stage for processing the output data in accordance with information contained in the first script files.

16. A computer program product comprising a computer useable medium having computer readable program code embodied therein for interfacing between first and second successive stages of an ASIC synthesis tool, said computer program product comprising:
computer readable program code for causing the computer to receive output data at an output of the first stage,
computer readable program code for causing the computer to automatically generate first script files, and
computer readable program code for causing the computer to feed said output data and said first script files to the second stage for processing the output data in accordance with information contained in the first script files.
